(19) United States
(12) Patent Application Publication
(10) Pub. No.: US 2016/0148842 A1
(43) Pub. Date: May 26, 2016

(54) DICING OF LOW-K WAFERS

(71) Applicant: NXP B.V., Eindhoven (NL)

(72) Inventors: Chung Hsiung Ho, Kaohsiung City (TW); Bensonil Chan, Kaohsiung (TW); Chien Kuo, Kaohsiung (TW)

(21) Appl. No.: 14/552,086

(22) Filed: Nov. 24, 2014

(51) Int. Cl. H01L 21/78; H01L 21/66; H01L 23/544

(52) U.S. Cl. CPC H01L 21/78; H01L 23/544; H01L 22/34

(57) ABSTRACT

Consistent with an example embodiment, there is a method for sawing a wafer substrate, the wafer substrate having a front-side surface containing active devices separated by saw lanes and a back-side surface having undergone back grinding, the saw lanes having process control monitor (PCM) devices present therein. The method comprises: with a blade of a first kerf, sawing the back-side surface in tracks corresponding to the saw lanes, to a first depth; laser grooving (LG) the saw lanes, to an LG depth, on the front-side surface of the wafer substrate until PCM devices are substantially removed, the LG having a preset beam diameter; and with a blade of a second kerf, the second kerf less than the first kerf, sawing the front-side surface of the wafer substrate about the center of the saw lanes until the active devices are separated from one another.

### FIELD

The disclosed is directed to the sawing of low-k wafers so as to minimize side wall damage along active device edges. In particular, the disclosed is directed to the removal any metal residues in the saw lanes between active device edges so as to reduce the risk of side wall cracking.

### BACKGROUND

As integrated circuit devices are tending toward demands for more performance in a smaller space, the search for materials has included the use of materials having a low dielectric constant (k<3.0). Use of materials with a k value lower than that of silicon dioxide (SiO₂) has reduced the interconnect structure capacitance. Further, with the replacement of aluminum (Al) interconnects with those of copper (Cu), the structural resistance is reduced. This emerging technology is becoming increasingly relevant in the myriad of systems and products on the market and in development.

The challenge in using the emerging technology impacts the manufacturing processes, especially during the sawing and dicing of low-k wafer substrate containing the fabricated active devices. There is a need for a processing technique that addresses this challenge.

### SUMMARY

The disclosed embodiments have been found useful in addressing the incidence of sidewall cracking during the sawing and singulation of a low-k wafer substrate having active devices. In some wafer substrates, process control monitor (PCM) circuits are laid out in the saw lanes. These PCM circuits are used to keep track of critical parameters during selected steps in the fabrication of the active devices and are constructed in parallel with the active devices during the photolithography and etching processes. Continual monitoring of the PCM values throughout the process may serve as an indicator of the production line stability and provide data for statistical process control (SPC). Further, if on a particular wafer, PCM values go out of acceptable ranges during a process step, the operator may choose to scrap the wafer rather than processing it further and incurring additional costs that are unnecessary. Like the active devices on the wafer substrate, there is metallization present on the PCM circuits. The sawing and singulation process may be adversely affected by the PCM metallization and contribute to the sidewall cracking.

In an example current process, a wafer's front-side surface has active devices, and PCM circuits in the saw lanes. Through a broad laser grooving, the PCM die are removed, the width of the laser grooving beam (W_{LG}) is close to that of the saw lane. A first blade of a first kerf width (W_{Z1}) which is less than the laser grooving width makes a cut to a depth greater than the depth of the active devices; the first blade is aligned to the center of the laser grooved saw lane. A second blade of a second kerf width (W_{Z2}) which is less than that of the first blade is aligned to the center of the first blade cut and makes a cut to a depth of the wafer substrate thickness; the wafer is singulated into individual devices. The widths of the cutting process follow the relationship of: W_{LG}>W_{Z1}>W_{Z2}.

Through a review of the current process, it is has been determined that the broad laser grooving kerf creates a large heat affected zone (HAZ). Shifts in the alignment of the first and second saw blades, resulting in a cut too close to the laser grooved edge induces sidewall cracking owing to the blades slicing through any remaining PCM metallization (not removed by laser grooving). A saw lane width currently in use is bout 80 μm. The trend is toward narrower saw lanes of about 60 μm or less. Thus, the current process is no longer suitable owing to the tighter alignment tolerances. With smaller saw lanes, the laser grooving width (W_{LG}) is reduced along with the kerf of the saws.

In an example embodiment according to the present disclosure, there is a method for sawing a wafer substrate, the wafer substrate having a front-side surface containing active devices separated by saw lanes and a back-side surface having undergone back grinding, the saw lanes having process control monitor (PCM) devices present therein. The method comprises mounting the wafer substrate onto a carrier tape on the front-side surface. With a blade of a first kerf, the back-side surface is sawed in tracks corresponding to the saw lanes, to a first depth. A carrier tape is applied to the back-side surface of the wafer substrate and the carrier tape is removed from the front-side surface. With the LG laser having a preset beam diameter, the saw lanes are laser grooved (LG), to an LG depth, on the front-side surface of the wafer substrate until PCM devices are substantially removed. With a blade of a second kerf, the second kerf less than the first kerf, the front-side surface of the wafer substrate is sawed about the center of the saw lanes until the active devices are separated from one another.

In another example embodiment, there is a method for sawing a wafer substrate, the wafer substrate having a front-side surface containing active devices separated by saw lanes and a back-side surface having undergone back-grinding, so that the wafer substrate has a back-grind thickness. The method comprises mounting the wafer substrate onto a first flexible foil carrier (FFC) on the front-side surface. With a blade of a first kerf, the back-side surface is sawed in tracks corresponding to the saw lanes, to a first depth, the first depth to at least one third of the back-grind thickness. A second FFC is applied to the back-side surface of the wafer substrate and the first FFC is removed from the front-side surface. Laser grooving (LG) the saw lanes on the front-side surface of the wafer substrate is performed to a depth of the remaining silicon left by first kerf blade; the LG has a second preset beam diameter. The wafer substrate is then separated into individual active device die.

In an example embodiment, there is semiconductor device die prepared by sawing and laser grooving. The semiconductor device die comprises a topside surface and an opposite underside surface. There are four vertical side faces; the four vertical side faces are perpendicular to the topside surface and opposite underside surface. Each of the four vertical side faces includes, a first tooling mark from a first kerf saw blade, a second tooling mark from a second kerf saw blade, and a heat affected zone (HAZ).

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments disclosed in connection with the accompanying drawings, in which:

FIG. 1 is a flow diagram of a wafer prepared according to an embodiment of the present disclosure;

FIGS. 2A-2C are simplified side views of a wafer dicing process according to an embodiment of the present disclosure;

FIGS. 2D-2E are side views of a wafer dicing process according to another embodiment of the present disclosure;

FIGS. 2F-2G are side views of a wafer dicing process according to another embodiment of the present disclosure;

FIGS. 3A-3C are side views of a wafer dicing process according to another embodiment of the present disclosure;

FIGS. 4A-4B is enlarged profile of the sawing process with respect to the second saw blade (W_{Z2}) comparing an existing process with that of the disclosure;

FIGS. 5A-5B are plots of experimental data showing the performance of the wafer sawing with the first blade (Z₁) according to the present disclosure;

FIGS. 6A-6B are plots of experimental data showing the performance of the wafer sawing with the laser grooving (LG) according to the present disclosure;

FIGS. 7A-7B are plots of experimental data showing the performance of the wafer sawing with the second blade (Z₂) according to the present disclosure; and

FIG. 8 is a scanning electron micrograph (SEM) cross-section of a wafer-substrate showing the depths of the first and second saw cuts, and laser grooving applied.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful in reducing the incidence of sidewall cracking and backside chipping active devices on low-k wafer substrates as they are sliced into individual product die. The sidewall cracking may be induced by the heat affected zone (HAZ) from laser grooving prior to sawing with blades, particularly in narrow saw lanes of 80 μm or less and on those wafers whose saw lanes are occupied by process control monitor (PCM) structures whose metallization is not completely removed by the laser grooving.

In an example embodiment according to the disclosure, a wafer substrate is sawed on the backside at predetermined locations in the saw lanes. The saw lanes may be ascertained through infra-red imaging from the back-side surface to the front-side surface of the wafer. In the example embodiment, the saw lane width is about 80 μm; in another example embodiment, the lane may be less; in others, more. During a first cut, with a saw blade of a first kerf (e.g., a “thick blade”), the wafer is sawed through the back side to a depth of about 75% of the post-grind thickness of the wafer. The width of the first kerf blade may be about 40 μm.

Wafer thickness, after back-side grinding, in an example process may be in the range of about 150 μm to about 250 μm. For example, a pre-grinding thickness, of an “eight-inch” wafer (200 mm) is about 725 μm; the pre-grinding thickness for a “six-inch” wafer (150 mm) is about 675 μm.

After the first cut, on the front-side surface of the wafer, about the center of the saw lanes, a laser grooving (L/G) process cuts through the top surface of the saw lanes. If any remaining metal from PCM circuits is present, the laser removes it. For an 80 μm saw lane width, the L/G process defines an opening of about 60 μm as it cuts through the metal and partially through the underlying silicon material.

More details of use of a laser in the dicing process may be found in U.S. patent application Ser. No. 13/687,110 of Sascha Moeller and Martin Lapke titled “Wafer Separation” filed on Nov. 28, 2012, published on May 29, 2014 as US 2014/0145294 A1, and is incorporated by reference in its entirety.

Further information on “low-k grooving” may be found in the product brochure titled, “Laser Application” of DISCO Corporation, Tokyo, Japan.

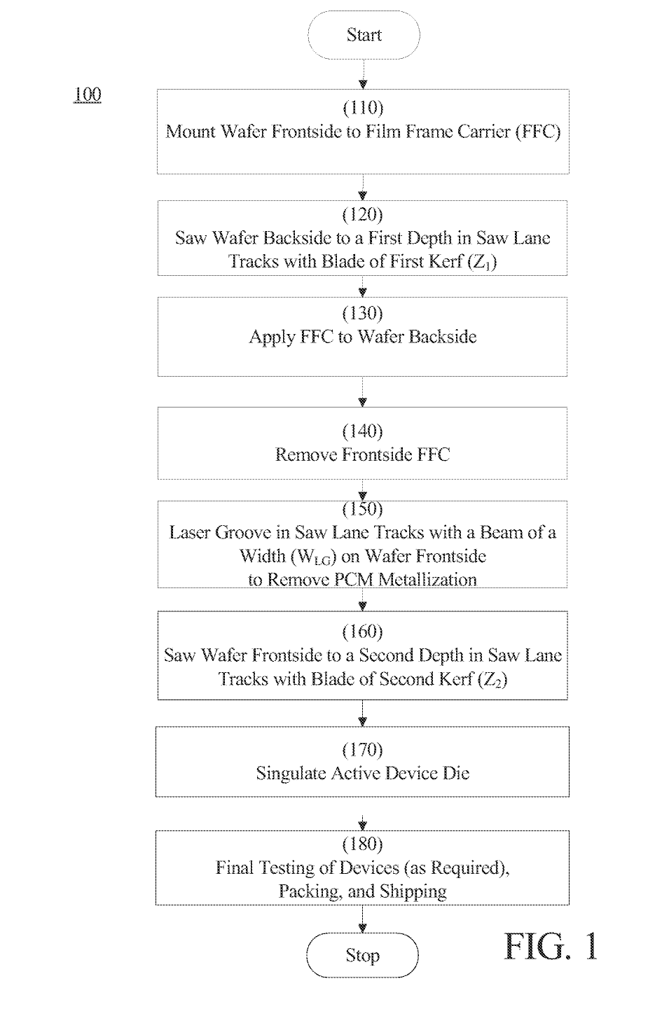

Refer to FIG. 1. In an example embodiment according to the present disclosure, a wafer substrate having active devices on its front side has undergone a back-side grinding. In step 110, on its front side, the wafer substrate is mounted onto a carrier tape. In step 120, on the back-side of the wafer substrate in the position corresponding to saw lane tracks, the back-side is sawed to a first depth with a blade of a first kerf (Z₁). In step 130, an additional carrier tape is applied to the wafer back-side 130. In step 140, the carrier tape is removed from the front-side of the wafer substrate. In step 150, between the active devices on the wafer front-side, in the saw lane tracks, a laser grooving takes place so as to remove any PCM material, especially the metallization. In step 160, with a blade of a second kerf (Z₂), the saw lane tracks are sawed to a second depth, which is at least the depth of the remaining silicon after the first sawing cut. In step 170, having cut through the saw lane tracks of the wafer substrate, the active device die are singulated. In step 180, as required by the user, the devices are packaged, tested, packed and shipped.

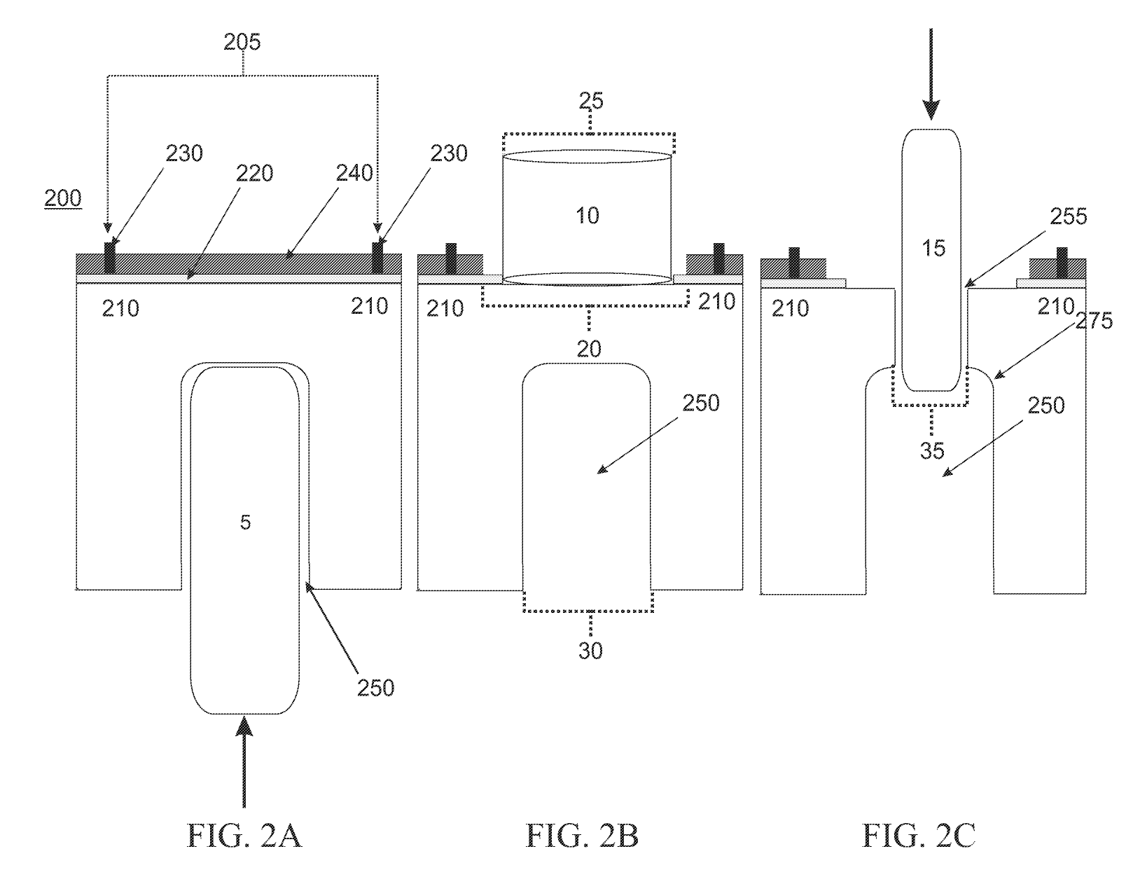

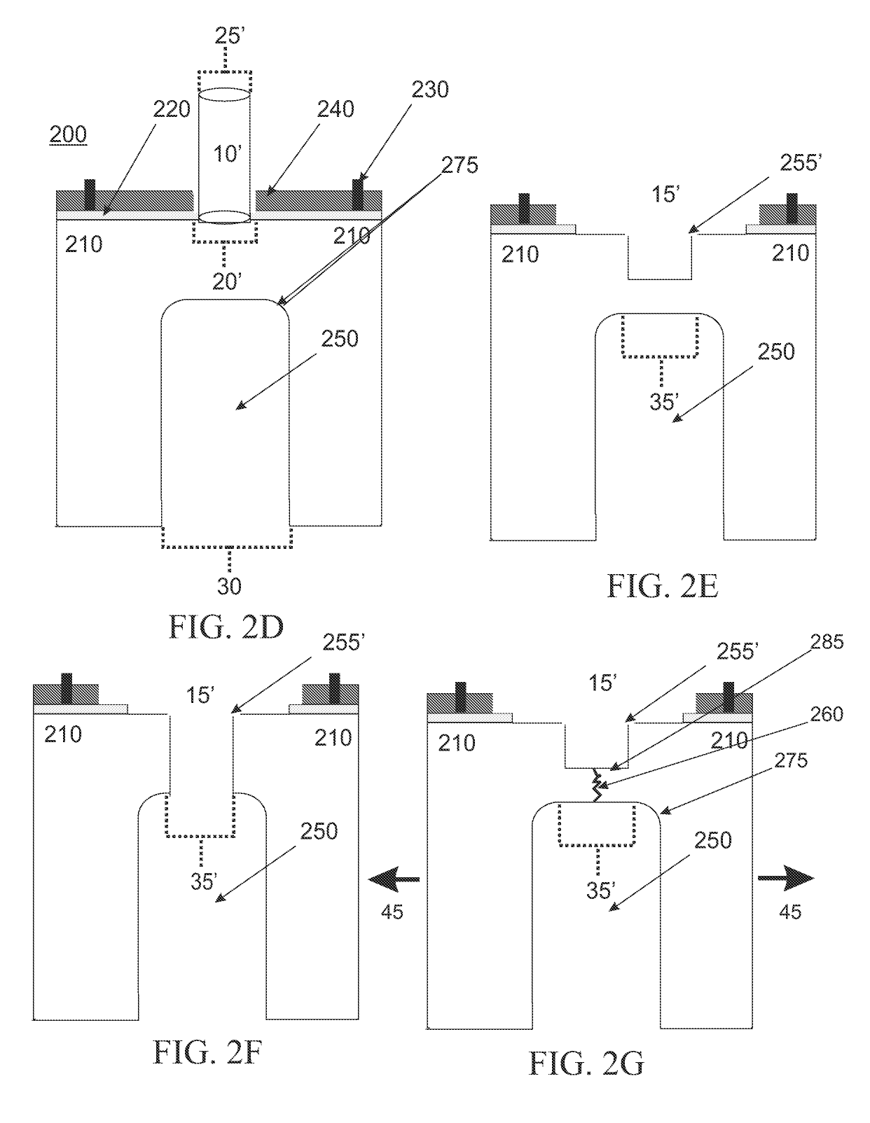

Refer to FIGS. 2A-2C. In an example embodiment, a wafer substrate has been thinned to less than 200 μm. An example wafer substrate 200 has a saw lane track 20 between adjacent active devices 210. The saw lane track 20 is about 80 μm wide; this is less than the distance 205 between the edges 230 of active device die. A blade 5 of a first kerf width (Z₁), of about 40 μm, makes a cut 250 (of a width 30) on the back-side surface (between adjacent device die 210) of the wafer substrate 200. The depth of the first cut is in the range of about 80 μm to about 100 μm. By laser grooving, a beam 10 (whose diameter 25 is about 60 μm) is applied and any PCM metallization 240 is removed so that the underlying dielectric layer 220 is exposed; in some processes the underlying dielectric layer 220 may be removed by the laser grooving, as well. Having completed the laser grooving, a blade 15 of a second kerf width (Z₂), of about 25 μm, slices through the saw lane track 20 on the front side of the substrate 200 and cuts through (with a second cut 35) the remaining silicon 255.

Refer to FIGS. 2D-2E. In another example embodiment, after the first cut with a blade of the first kerf (Z₁) as shown in FIG. 2A, the laser grooving with a beam 10′ where diameter 25′ is about 8 μm to about 12 μm is applied to remove any PCM metallization 240, as before.

Refer to FIG. 2F. In a first option, the second saw blade 15′ may saw, with a kerf 35′, completely through the area defined by the laser grooving, so that the wafer die 210 may be separated.

Refer to FIG. 2G. In a second option, the second saw blade 15′ may partially saw the laser grooved defined area 35′. As the wafer substrate remains attached to the flexible foil carrier, the process stretches in a direction 45; the flexible foil carrier, cleaves apart, for example, the wafer die 210 at location 260, into separate individual devices. Note a step profile 275, is present after the two saw cuts and an additional projection 285 is present after the cleaving apart of the wafer die 210. Upon examining a completed device, these attributes would be visible through any appropriate imaging technique.

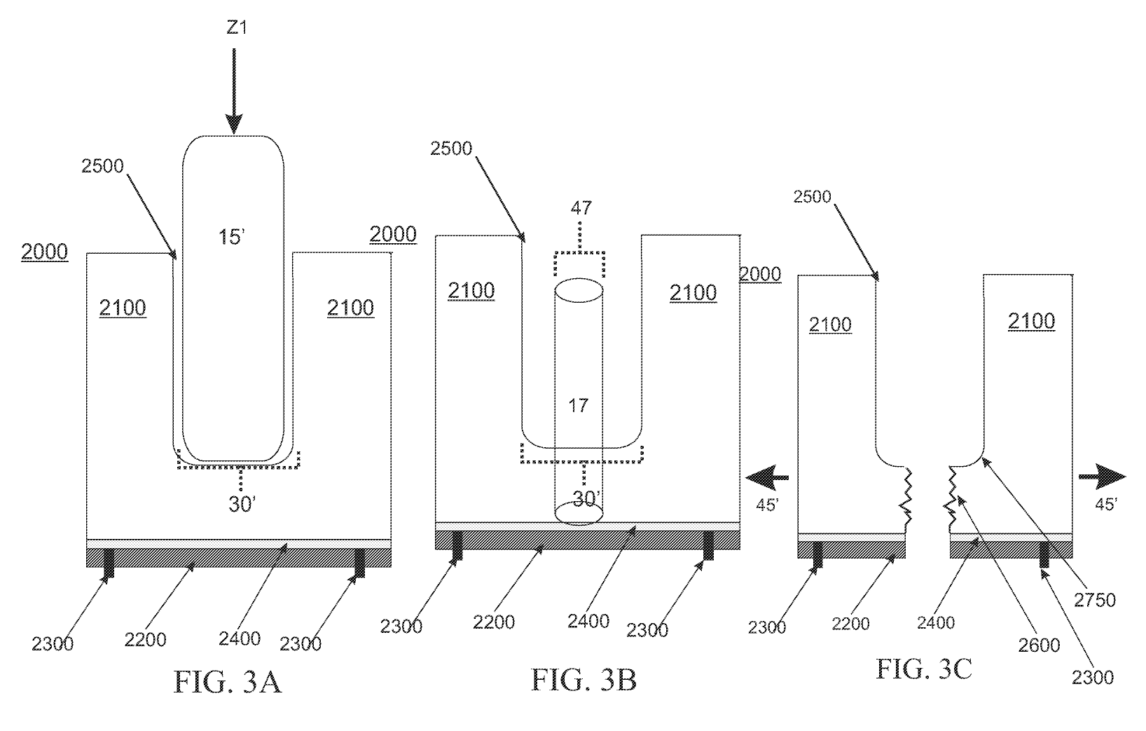

Refer to FIGS. 3A-3C. In another example embodiment, the cutting and separation of the wafer substrate 2000 occurs from the underside surface, away from active device die circuits. A Z1 blade 15′ slices substantially through the substrate 2100, leaving a cut 30.′ Prior to cutting, of course, the location of the saw lanes would be determined through imaging from the underside surface (e.g., infra-red). A laser beam 17 of a width 47 which would be about 8 μm to 12 μm, cuts through to the side containing active device die on edges of active device die 2300. Also metallization layers 2200 and PCM patterns 2400 are cut. The laser may either groove cut completely or create HAZ zone which will cleave apart upon force 45′ stretching the flexible foil carrier. The resulting cleaved profile 2600 is present, as well as a step profile 2750.

In another example embodiment, a second cut Z2 with a blade of narrower kerf than that of the Z1 blade may be used in lieu of laser grooving.

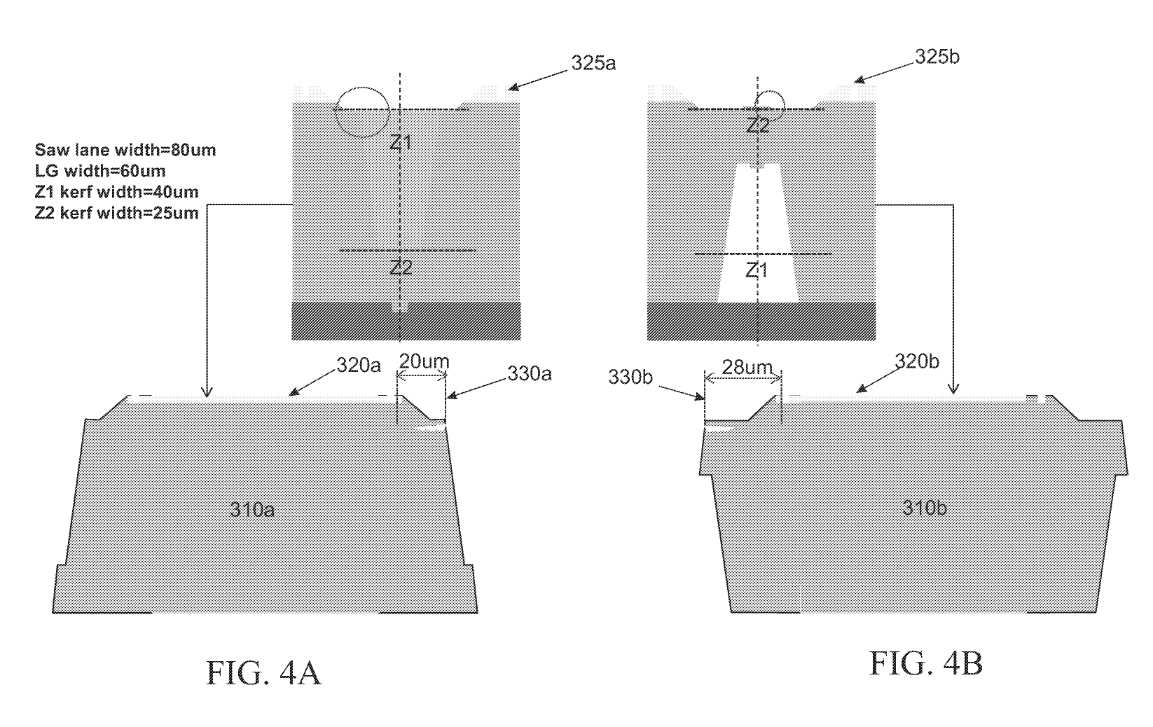

Refer to FIG. 4A. In an example process, a silicon device 310a with active device area 320a had been sawed on the front-side surface with a blade of a larger kerf (Z₁), followed by a laser grooving, and then followed by a blade with a smaller kerf (Z₂). The distance 330a from the saw cut edge to the active device boundary 325a is about 20 μm. The saw lane with is about 80 μm, the laser grooving width is about 60 μm, the Z₁ kerf is about 40 μm and the Z₂ kerf is about 25 μm.

Refer to FIG. 4B. In accordance with the present disclosure, with the same blade kerfs Z₁ and Z₂, the active devices are prepared by the process as described in connection with FIG. 1. The silicon device 310b has an active device area 320b. The distance 330b from the device edge 325b and the active device is about 28 μm. The added distance between 330a and 330b, reduces the likelihood of device damage owing to shifts in the sawing blade Z₂; there is a larger process window.

The present disclosure, in having a larger process window to accommodate the Z₂ shift, reduces the likelihood of backside chipping. The second blade lifetime is extended because of the shallower depth required to saw and separate the device die. Further, in that the blade is cutting at a shallower depth, there is less vibration from blade imperfections; the cut is more accurate with less variation. The heat affected zone (HAZ) of the laser grooving can be reduced because the smaller kerf (Z₂) of the second blade does not require as large a diameter laser beam to remove undesired material in the saw lanes.

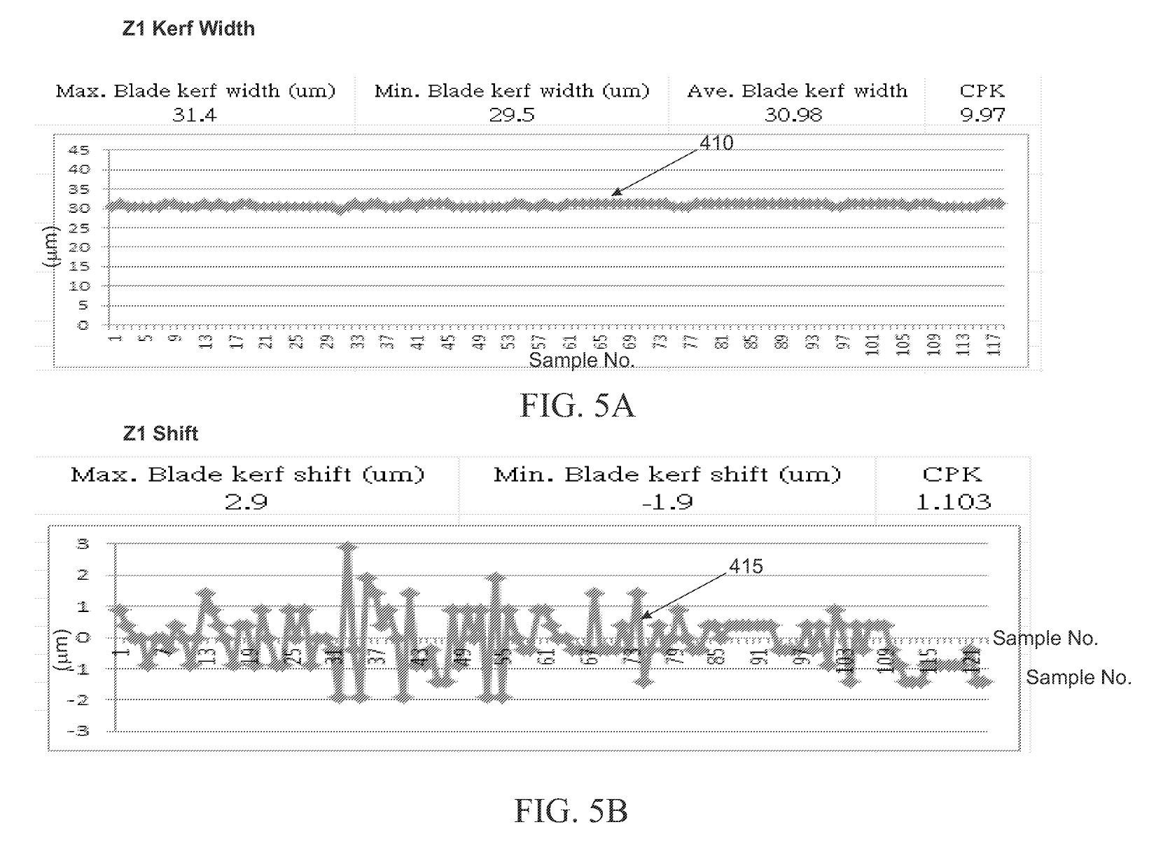

In developing the disclosed technique, the performance of the first and second saw blades and the laser grooving was reviewed and analyzed. Refer to FIGS. 5A-5B. For the first blade (Z₁), about 117 measurements had been taken and plotted for each sample v. the kerf width expressed in μm. The curve 410 is expressed in FIG. 5A. The maximum blade kerf width was 31.4 μm and a minimum blade kerf width was 29.5 μm; the average kerf width was 30.98 μm.

During the sawing, the first blade (Z₁) had exhibited shift as each sample cut was made. There was a maximum shift of about 2.9 μm and a minimum shift of about −1.9 μm about a “zero line” center (i.e., 0 μm of shift). The C_{PK} is about 1.103. Curve 415 is expressed in FIG. 5B. C_{PK} is the process capability index which is a statistically measure of the process capability: the ability of a process to produce output with specification limits. In example production systems, an existing process may have a C_{PK}=1.33, where the C_{PK} for a safety or critical parameter for a new process may be around C_{PK}=1.67. A six-sigma quality process has a C_{PK}=2.00. Processes not quite stabilized may C_{PK}=1.00 (which is about a three-sigma process).

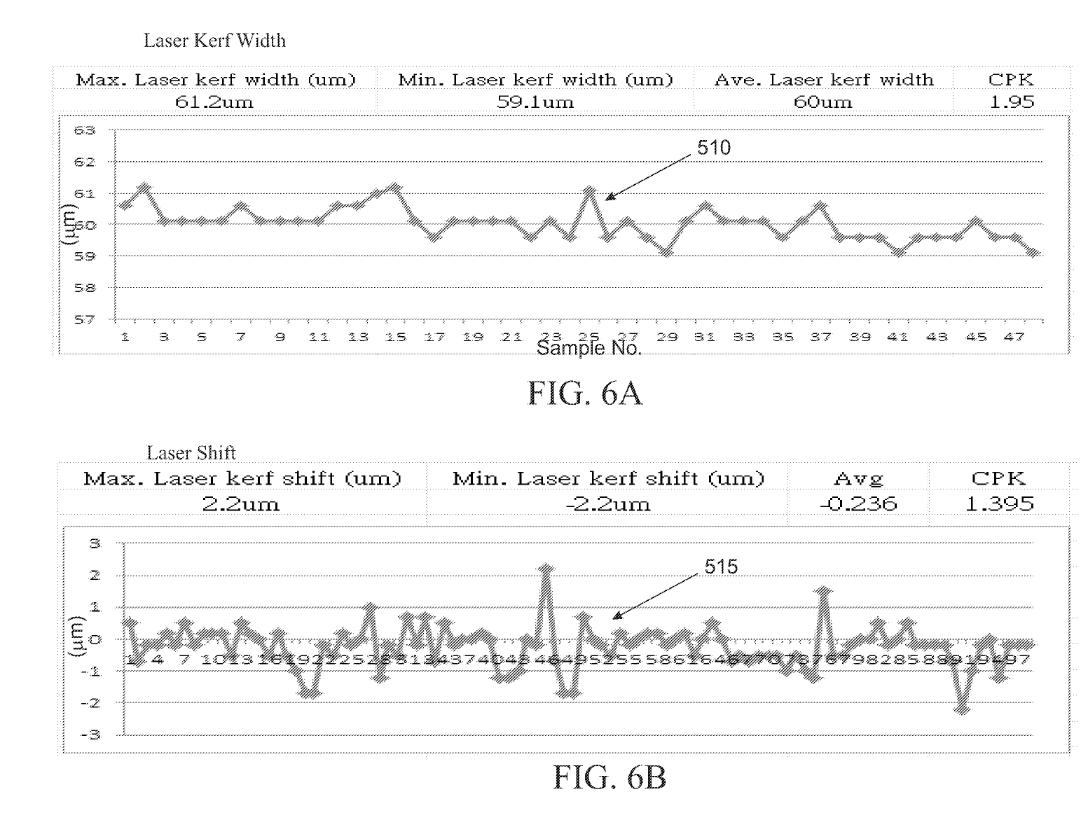

Refer to FIGS. 6A-6B. The laser grooving (LG) kerf had been plotted as shown in curve 510. The laser kerf had a maximum width of about 61.2 μm and a minimum width of about 59.1 μm with an average of about 60 μm (which is the nominal setting for this example process). The C_{PK} was about 1.95.

During the laser grooving, the maximum shift was about 2.2 μm and the minimum shift was about −2.2 μm with an average of about −0.236 μm a “zero line” center (i.e., 0 μm of shift). The laser grooving shift is plotted as curve 515 in FIG. 5B. The C_{PK} was about 1.395.

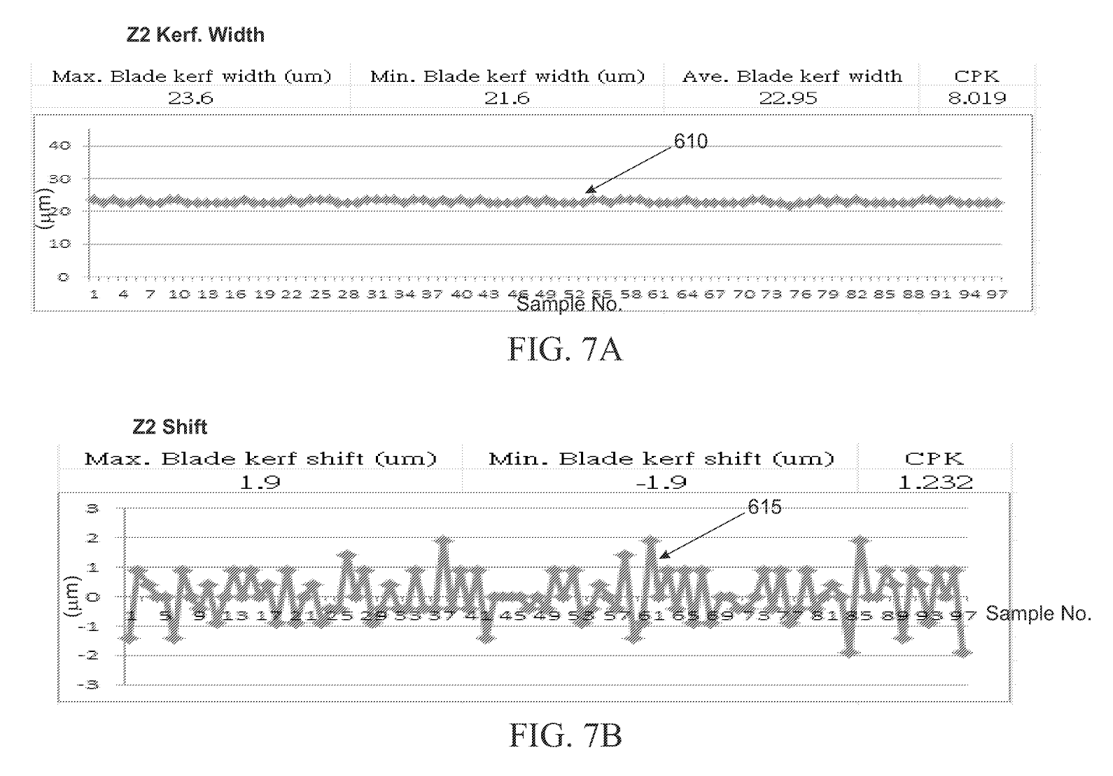

Refer to FIGS. 7A-7B. For the second blade (Z₂), about 97 measurements had been taken and plotted for each sample v. the kerf width expressed in μm. The curve 610 is expressed in FIG. 7A. The maximum blade kerf width was 23.6 μm and a minimum blade kerf width was 21.6 μm; the average kerf width was 22.95 μm. The process capability C_{PK} was estimated at 9.97. The blade kerf being a constant would not exhibit statistically significant variation.

During the sawing, the second blade (Z₂) had exhibited shift as each sample cut was made. There was a maximum shift of about 1.9 μm and a minimum shift of about −1.9 μm about a “zero line” center (i.e., 0 μm of shift). The C_{PK} is about 1.232. Curve 615 is plotted in FIG. 7B.

By performing the sawing with the first cut of Z₁ on the back-side surface of the wafer substrate, the maximum shift to which the active devices would be exposed, has been reduced from 2.9 μm to about 1.9 μm. Thus, the smaller kerf of the second cut of Z2, after the laser grooving, with its reduced shift, lessens the probability of the sawing/singulation process damaging active areas of the integrated circuit device die.

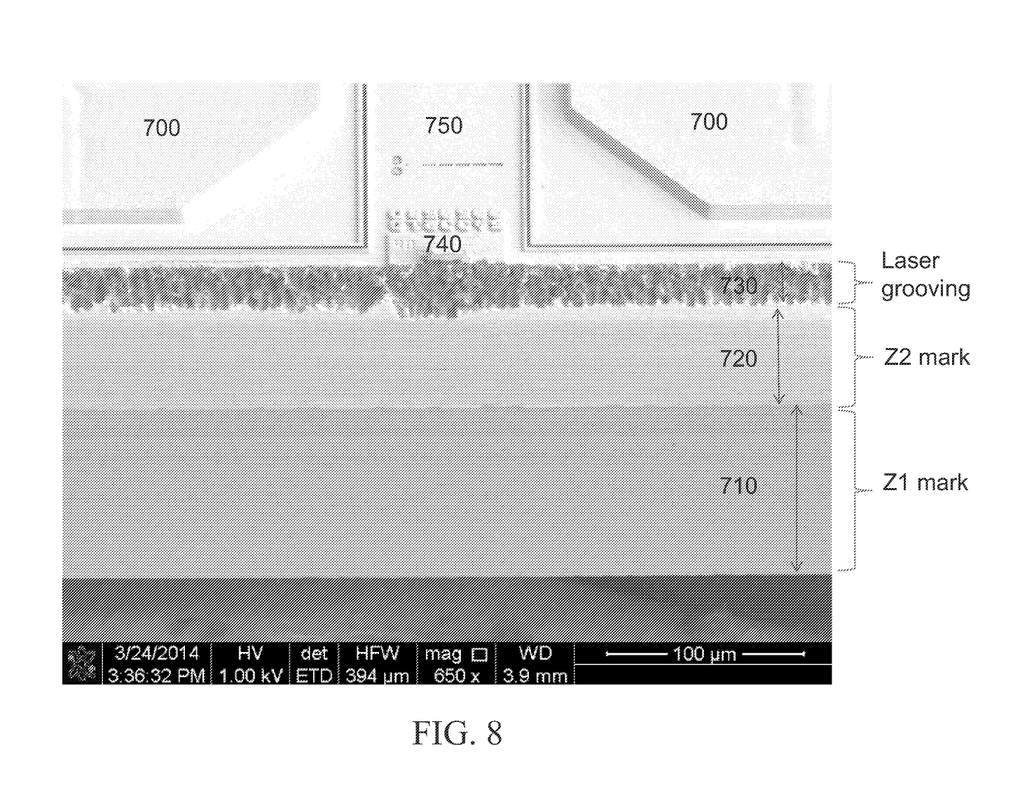

Refer to FIG. 8. In a scanning electron micrograph, a wafer substrate with active device die 700 with saw lanes 750, has been prepared in accordance with an embodiment in the present disclosure. The first kerf blade (Z₁) has sawed the substrate to a prescribed depth 710, the laser grooving has removed the undesired PCM metallization 740 down to bare silicon and has a modification zone of a depth 730. The second kerf blade (Z₂) cuts through the remaining silicon in the saw lane of a depth 720. For an example substrate of a total thickness of about 300 μm, the Z₁ cutting depth from the back side is about 100 μm, a third of the total thickness. From the front side, the laser grooving depth is about 15 μm. The Z₂ cutting depth from the front side, through the remaining silicon is about 200 μm, or about two thirds of the total substrate thickness.

The disclosed embodiments may be useful in devices whose saw lanes are less than 80 μm. For example, the Width_{Z1}>Width_{LG}>Width_{Z2}=60 μm>40 μm>25 μm. However, per the disclosure, the Width_{Z1} is no longer constrained. With a narrower saw lane, the Z₂ blade with a narrower kerf is more accurate. The depth at which the blade performs its cutting is less than current methods; the lower depth improves cutting accuracy. For example, for a Width_{Z2}=25 μm, the accuracy of the blade is ±3 μm; owing to blade vibration, the acceptable kerf is about 1.1× blade width. Thus, a 25 μm would have an acceptable kerf of about 27.5 μm.

As discussed in reference to FIGS. 2A-2G, during the cutting and laser grooving process, invariably tooling marks will be left on the processed surfaces (i.e., “tooling marks”). For a saw blade, the tooling marks may manifest themselves as marks, grooves, or steps. For laser grooving, the change in the crystalline structure of the affected silicon is apparent. In the processes according to the present disclosure, the different kerfs of the saw blades may be apparent in a step profile on the vertical side surfaces of a singulated device die.

More detailed information on saw marks in silicon wafers may be found in a paper titled, “Quantitative Classification of Saw Marks of Silicon Wafers,” of A. Lawerenz, S. Dauwe, and F.-W. Schulze. (Pre-Print for the 21^{st} European Photovoltaic Solar Energy Conference and Exhibition, Dresden, Germany, September 2006).

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the invention will be apparent to persons skilled in the art without departing from the spirit and scope of the invention as defined in the appended claims.

1. A method for sawing a wafer substrate, the wafer substrate having a front-side surface containing active devices separated by saw lanes and a back-side surface having undergone back grinding, the saw lanes having process control monitor (PCM) devices present therein, the method comprising:
mounting the wafer substrate onto a carrier tape on the front-side surface;
with a blade of a first kerf, W_{Z1}, sawing the back-side surface in tracks corresponding to the saw lanes, to a first depth;
applying carrier tape to the back-side surface of the wafer substrate;
removing the carrier tape from the front-side surface;
laser grooving (LG) the saw lanes, to an LG depth, on the front-side surface of the wafer substrate until PCM devices are substantially removed, the LG having a preset beam diameter, W_{LG}; and
with a blade of a second kerf, W_{Z2}, the second kerf less than the first kerf, sawing the front-side surface of the wafer substrate about the center of the saw lanes to enable the separation of the active devices from one another;
wherein W_{LG}>W_{Z1}>W_{Z2}.

2. The method as recited in claim 1, wherein the separation of the active devices from one another, is selected from at least one of the following:
sawing the front-side surface of the wafer substrate until the active devices are completely separated from one another; and
sawing the front-side surface of the wafer substrate to a partial depth, such that the remaining wafer substrate material between active devices cleaves apart upon stretching of the carrier tape.

3. The method as recited in claim 1, the first depth is determined by a post-grind thickness of the wafer substrate and the first depth is at least 50% of the post-grind thickness.

4. The method as recited in claim 3, wherein the LG depth goes beyond the removal of the PCM devices until bare silicon is exposed.

5. The method as recited as recited in claim 4, wherein the first kerf is in the range about 80 μm to about 60 μm, wherein the LG diameter is in the range of about 60 μm to about 40 μm, and wherein the second kerf is about 25 μm.

6. The method as recited in claim 5, wherein the saw lanes have a width in the range of about 80 μm to about 60 μm.

7-12. (canceled)
